(19) United States
(12) Patent Application Publication
(10) Pub. No.: US 2006/0294032 A1
(43) Pub. Date: Dec. 28, 2006

(54) Fee calculation system for electrical energy consumption of motor drive and method for the same

(75) Inventors: Cheng-Te Chen, Taoyuan Hsien (TW); Yu-Bin Chao, Taoyuan Hsien (TW); Chia-Hsiang Yang, Taoyuan Hsien (TW)

Correspondence Address: HDSL, 4331 STEVENS BATTLE LANE, FAIRFAX, VA, 22033, US

(73) Assignee: Delta electronics, Inc.

(21) Appl. No.: 11/159,168

(22) Filed: Jun. 23, 2005

(51) Int. Cl. G01R 21/133

(52) U.S. Cl. 705/412

(57) ABSTRACT

A fee calculation system for electrical energy consumption of motor drive and method for the same. The electrical power consumption for the motor drive and for a motor driven by the motor drive are calculated and displayed. An instantaneous load power of the motor is calculated according to an output voltage, an output current and a power factor of the motor drive. The total instantaneous consumption power is the sum of the instantaneous load power of the motor and the internal power of the motor drive. The total instantaneous consumption power is converted to power consumption per hour and is then multiplied with the operation hour to obtain the total electrical energy consumption. The total electrical energy consumption is multiplied with a fee schedule input by user to obtain the total fee for the electrical energy consumption. The total fee is then shown on a display of the motor drive.

### BACKGROUND OF THE INVENTION

1. Field of the Invention

The present invention relates to a fee calculation system for an electrical equipment and a method for the fee calculation, and especially to a fee calculation system for the electrical energy consumption of a motor drive and method for the fee calculation.

2. Description of Prior Art

Motor drives are used to control a rotation speed of a motor to be within a predetermined range. Therefore, the motor drive is also referred to as invertor. The motor drive can provide adjustable output power according to actual load, thus preventing power waste problem occurred in conventional fixed-speed motor. The motor drive has been extensively used for household usage such as air conditioner, refrigerator and microwave oven. The motor drive is more interested in industrial usage because the industrial usage will consume more electrical power.

The motor drive has energy saving function; nevertheless, user still cannot know the electrical energy consumption of the motor drive per se. With reference to FIG. 1, the motor drive 3 is arranged between a motor 2 and an electrical meter 1 and one end of the electrical meter 1 is electrically connected to a power source 11. Therefore, user needs to calculate the fee of consumed electrical energy by multiplying the reading output of the electrical meter 1 with a unitary cost of electrical energy. It is inconvenient for user. Moreover, the electrical meter 1 may be shared by a plurality of electrical equipments rather than dedicated to the motor drive 3. Therefore, the energy consumption for the motor drive 3 is difficult to know for the user. Moreover, the electrical meter 1 can only show an accumulative consumed energy rather than a precise consumed energy within a time period. Moreover, the electrical meter 1 is generally provided by a power company to count the electrical energy consumption of a house. It is not economic to provide independent power meter to each electrical equipment.

Moreover, the conventional motor drive has only display and input unit for display and input function; therefore, the conventional motor drive does not support calculation function to electrical energy consumption. It is desirable to provide value-added function to the motor drive without excessive cost increment.

### SUMMARY OF THE INVENTION

The present invention provides a fee calculation system for electrical energy consumption of motor drive and method for the same.

Accordingly, the present invention provides a fee calculation system with a motor drive connected to a motor to obtain an output voltage, an output current and a power factor of the motor drive. The instantaneous load power of the motor is calculated based on above result and the total instantaneous consumption power is obtained by adding the internal power of the motor drive. The total instantaneous consumption power is then multiplied with the operation hour and the fee schedule input by user to obtain the total fee for the electrical energy consumption. The total fee is then shown on a display of the motor drive. Therefore, user can know the fee for operating a motor drive directly for a specific time period.

### BRIEF DESCRIPTION OF DRAWING

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 shows a block diagram of a conventional motor drive.

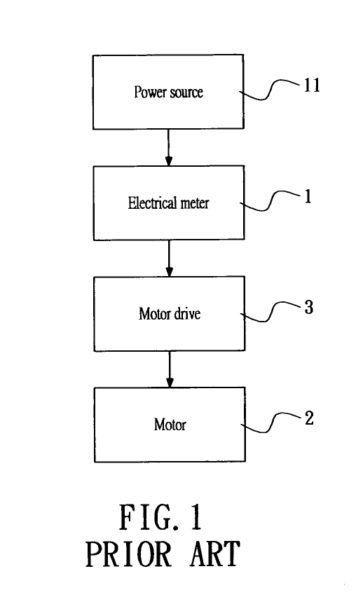

FIG. 2 shows a block diagram of the present invention.

FIG. 3 shows a flowchart of the fee calculating method of the present invention.

FIG. 4 shows a block diagram of the motor drive according to the present invention.

### DETAILED DESCRIPTION OF THE INVENTION

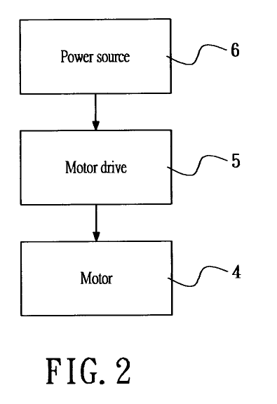

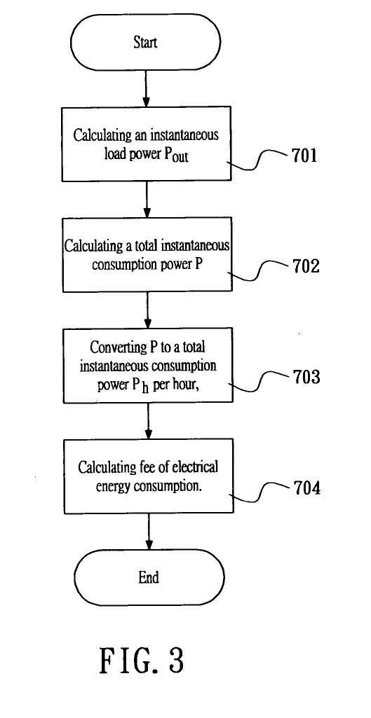

With reference to FIGS. 2 and 3, according to the fee calculation method and system for electrical energy consumption of motor drive of the present invention, the motor drive 5 is coupled between an input of a motor 4 and a power source 6. The calculated fee will be shown on a display. The method of the present invention will be detailed below.

The instaneous load power P of a 3 phase (3 Φ) motor is
P=3×V×I×cosθ
where V stands for voltage, I stands for current, θ stands for power factor angle and cosθ stands for power factor.

Moreover, the instaneous load power for single phase is V×I×cosθ

With reference to FIG. 3, the instaneous load power Pₒᵤₜ is first calculated (step 701), wherein the electrical voltage V, the electrical current I and the power factor cosθ are obtained from the motor drive 5 to calculate the instaneous load power Pₒᵤₜ of the motor 4.

Afterward, the total instantaneous consumption power P is calculated (step 702), wherein the total instantaneous consumption power is the sum of the instantaneous load power Pₒᵤₜ of the motor and the internal consumption power Pᵢ of the motor drive. Namely, P=Pₒᵤₜ+Pᵢ.

The internal consumption power Pᵢ of the motor drive accounts for the standby power consumption and the consumption power of power module. The standby power consumption is measured in a long-term base and the consumption power of power module is measured for various operation conditions.

The total instantaneous consumption power is converted to power consumption per hour Pₕ in step 703, namely, Pₕ=3600×P.

The total fee for the electrical energy consumption is then calculated (step 704), wherein the power consumption per hour Pₕ is multiplied with the operation hour T to obtain the total electrical energy consumption. Afterward, the total electrical energy consumption is multiplied with a fee schedule E_{c} input by user to obtain the total fee M for the electrical energy consumption. Namely, M=P×T×E_{c}, where T is operation hour of the motor drive in the unit of hour.

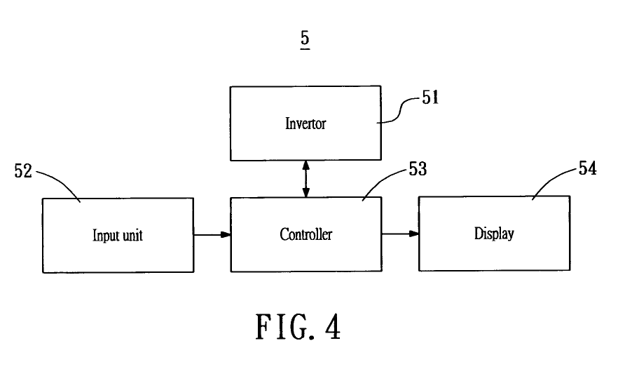

The above-mentioned fee calculation method can be implemented in the motor drive shown in FIG. 4. As shown in this figure, the motor drive 5 comprises an invertor 51, a controller 53 coupled to the invertor 51, an input unit 52 is coupled to the controller 53 and a display 54 is coupled to the controller 53.

The controller 53 has a built-in program for performing the above-mentioned fee calculation method. The controller 53 obtains the electrical voltage V, the electrical current I and the power factor angle θ from the motor drive 5 to calculate the instaneous power Pₒᵤₜ of the motor 4. Afterward, the fee schedule E_{c} and a particular time period are input through the input device 52. The controller 53 calculates the fee for the electrical energy consumption and then shows the calculated fee to the display 54.

According to above-mentioned method and system, the motor drive 5 can calculate the fee for the electrical energy consumption per se and shows the fee on the display 54 thereof. Moreover, the calculated fee can also be accessed or displayed remotely for further processing. Moreover, memory unit (not shown) can also be incorporated into the motor drive 5 to calculate an accumulative electrical energy and associated fee.

The above-mentioned motor drive 5 can calculate the consumed electrical energy and associated fee for the motor 4 and no additional measuring instrument is needed. Therefore, the wiring is simplified and the cost is reduced.

Although the present invention has been described with reference to the preferred embodiment thereof, it will be understood that the invention is not limited to the details thereof. Various substitutions and modifications have suggested in the foregoing description, and other will occur to those of ordinary skill in the art. Therefore, all such substitutions and modifications are intended to be embraced within the scope of the invention as defined in the appended claims.

What is claimed is:

1. A method for calculating fee of electrical energy consumption in a motor drive, comprising the steps of:
a) calculating an instantaneous load power Pₒᵤₜ according to an output voltage, an output current and a power factor of the motor drive;
b) calculating a total instantaneous consumption power P by adding the instantaneous load power Pₒᵤₜ with an internal consumption power Pᵢ of the motor drive;
c) multiplying the total instantaneous consumption power P with an operation time of the motor drive and a fee schedule E_{c} to obtain the fee M of the electrical energy consumption.

2. The method a motor drive as in claim 1, further comprising a step between the steps b) and c):
converting the total instantaneous consumption power P in unit of second to a total instantaneous consumption power Ph in unit of hour, wherein the operation time of the motor drive in the step c) is also represented in a unit of hour.

3. The method as in claim 1, wherein the internal consumption power Pᵢ of the motor drive includes a standby power consumption and a consumption power of a power module.

4. The method as in claim 3, wherein the standby power consumption is measured by a long-term base for the motor drive.

5. The method as in claim 3, wherein the consumption power of the power module is measured for various operation conditions.

6. A system for calculating fee of electrical energy consumption in a motor drive, comprising
an invertor for controlling a motor with a variable speed;
a controller operatively connected to the invertor and storing a program for calculating a fee of electrical energy consumption in the invertor, the controller calculating the fee of electrical energy consumption in the invertor according to an output voltage, an output current and a power factor of the invertor;
a display operatively connected to the controller and showing the fee calculated by the controller; and
an input unit operatively connected to the controller and used to input an operation time and a fee schedule for calculating the fee of electrical energy consumption.
